(19) United States
(12) Patent Application Publication
(10) Pub. No.: US 2014/0061743 A1
(43) Pub. Date: Mar. 6, 2014

(54) SEMICONDUCTOR DEVICES AND METHOD OF FABRICATING THE SAME

(71) Applicant: Samsung Electronics Co., Ltd., Suwon-si (KR)

(72) Inventors: Hyunchul Kim, Seoul (KR); Jae-Seok Kim, Hwaseong-si (KR); Chan-Hong Park, Suwon-si (KR)

(21) Appl. No.: 13/945,279

(22) Filed: Jul. 18, 2013

(30) Foreign Application Priority Data
Aug. 30, 2012 (KR) 10-2012-0095921

(51) Int. Cl. H01L 27/088

(52) U.S. Cl. CPC H01L 27/088
USPC 257/296; 257/368

(57) ABSTRACT

Provided are a semiconductor device and a method of fabricating the same. The semiconductor device may include a substrate, a device isolation layer defining one or more active regions at the substrate, and one or more gate lines buried in the substrate. Each of the gate lines comprises a first portion on the device isolation layer and a second portion on an active region of the active regions. A top surface of the first portion is lower than a top surface of the second portion.

### CROSS-REFERENCE TO RELATED APPLICATIONS

This U.S. non-provisional patent application claims priority under 35 U.S.C. §119 to Korean Patent Application No. 10-2012-0095921, filed on Aug. 30, 2012, in the Korean Intellectual Property Office, the entire contents of which are incorporated herein by reference.

### BACKGROUND OF THE INVENTION

Example embodiments of the inventive concept relate to a semiconductor device and a method of fabricating the same, and in particular, to a semiconductor device having buried gate lines and a method of fabricating the same.

Due to their small-size, multifunctionality, and/or low-cost characteristics, semiconductor devices are considered important elements in the electronic industry. Some semiconductor devices may include a memory device for storing data, a logic device for processing data, and/or a hybrid device capable of performing various memory storage and data processing functions simultaneously.

Due to the increasing demand for electronic devices requirements for a fast speed and/or low power consumption, the semiconductor device must be constructed to have a fast operating speed and/or a low operating voltage. To satisfy these technical requirements, the semiconductor device needs high integration density, that is, more elements per area. However, an increase in the integration density may lead to a decrease in the reliability of the semiconductor device. Thus, there have been conducted a variety of studies on new technology to improve both the integration density and the reliability of the semiconductor device.

### SUMMARY

Example embodiments of the inventive concept provide semiconductor devices with improved refresh property and methods of fabricating the same.

According to some embodiments of the inventive concepts, a semiconductor device may include a substrate; a device isolation layer defining one or more active regions at the substrate; and one or more gate lines buried in the substrate, the gate lines crossing the active regions, wherein each of the gate lines comprises: a first portion on the device isolation layer; and a second portion on an active region of the active regions, and wherein a top surface of the first portion is lower than a top surface of the second portion.

In some embodiments, a bottom surface of the first portion is lower than a bottom surface of the second portion.

In some embodiments, the top surface of the first portion is higher than a bottom surface of the second portion.

In some embodiments, the device isolation layer comprises a first region and a second region crossing the gate lines, a distance between active regions of the one or more active regions adjacent to the first region is greater than a distance between active regions of the one or more active regions adjacent to the second region, and the first portion is positioned on the first region.

In some embodiments, the gate lines further comprise a third portion positioned on the second region, and wherein the top surface of the first portion is lower than a top surface of the third portion.

In some embodiments, a bottom surface of the first portion is substantially coplanar with a bottom surface of the third portion.

In some embodiments, the device further comprises a doped region formed in each of the active regions, wherein the doped region comprises a first doped region between the gate lines and a second doped region between the gate lines and the device isolation layer.

In some embodiments, the first doped region extends into the substrate having a depth that is greater than a depth of the second doped region.

In some embodiments, the gate lines comprise a first gate line buried in the active regions and a second gate line buried in the device isolation layer, and wherein a distance from a top surface of the second doped region to a top surface of the first portion of the second gate line is greater than a distance from a top surface of the second doped region to a top surface of the second portion of the first gate line.

In some embodiments, the second gate line is separated from the second doped region by the device isolation layer.

In some embodiments, the device further comprises bit lines provided on the substrate and connected to the first doped region; and a capacitor on the substrate and coupled to the second doped region.

According to some embodiments of the inventive concepts, a method of fabricating a semiconductor device may comprise forming a device isolation layer on a substrate to define one or more active regions; forming one or more conductive patterns that cross the active regions and that are buried in the substrate; and forming one or more gate lines using the conductive patterns, wherein each of the conductive patterns comprises a first portion on the device isolation layer and a second portion on the active region, and wherein the forming of the gate lines comprises etching upper portions of the first portions of the conductive patterns.

In some embodiments, the forming of the device isolation layer comprises forming a first region and a second region crossing the conductive patterns, wherein a distance between the active regions adjacent to the first region is greater than a distance between the active regions adjacent to the second region, and wherein the first portion is formed on the first region.

In some embodiments, the forming of the gate lines comprises: forming one or more mask patterns on the conductive patterns; etching the upper portions of the first portions using the mask patterns as an etch mask; and removing the mask patterns, wherein a top surface of the first portion is formed at a level lower than a top surface of the second portion.

In some embodiments, the method further comprises forming one or more capping patterns on the gate lines.

According to some embodiments of the inventive concepts, a semiconductor device may include a substrate, a device isolation layer defining a plurality of active regions at the substrate, and first and second gate lines in the substrate that cross the active regions, wherein each of the first and second gate lines comprises a first portion on the device isolation layer, and a second portion on an active region of the active regions, and wherein a top surface of the first portion of the second gate line is lower than a top surface of the second portion of the first gate line.

In some embodiments, a distance between the top surface of the first portion of the second gate line and a top surface of the device isolation layer at which the first gate line is positioned is greater than a distance between the top surface of the second portion of the first gate line and the top surface of the active region at which the first gate line is positioned, and wherein the top surface of the device isolation layer and the top surface of the active region at which the first gate line is positioned extend along a same axis.

In some embodiments, the device further comprises a doped region formed in each of the active regions, wherein the doped region comprises a first doped region between the first gate line and a third gate line, and a second doped region between the first and second gate lines.

In some embodiments, the first doped region extends into the substrate having a depth that is greater than a depth of the second doped region.

In some embodiments, a distance from a top surface of the second doped region to a top surface of the first portion of the second gate line is greater than a distance from a top surface of the second doped region to a top surface of the second portion of the first gate line.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1A is a plan view illustrating a semiconductor device according to example embodiments of the inventive concept.

FIG. 1B is a sectional view taken along a line I-I′ of FIG. 1A.

FIG. 1C is a sectional view taken along a line II-II′ of FIG. 1A.

FIGS. 2A through 9A are plan views illustrating a method of fabricating a semiconductor device according to example embodiments of the inventive concept.

FIGS. 2B through 9B are sectional views taken along lines I-I′ of FIGS. 2A through 9A, respectively.

FIGS. 2C through 9C are sectional views taken along lines II-IP of FIGS. 2A through 9A, respectively.

FIG. 10 is a schematic block diagram illustrating an example of an electronic system including semiconductor devices according to embodiments of the inventive concept.

FIG. 11 is a schematic block diagram illustrating an example of a memory card including semiconductor devices according to embodiments of the inventive concept.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

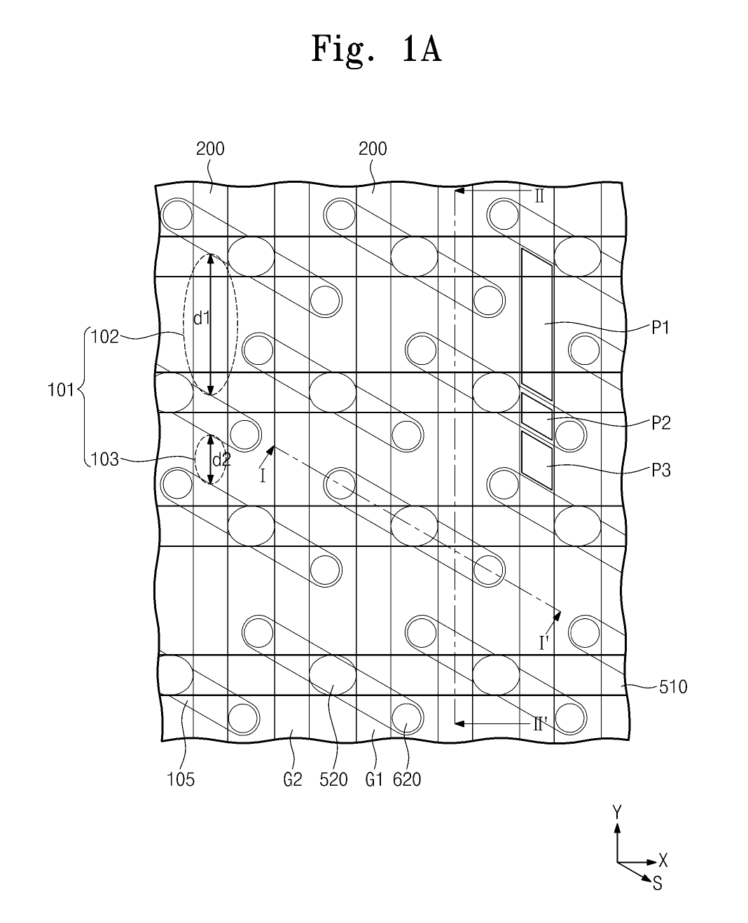

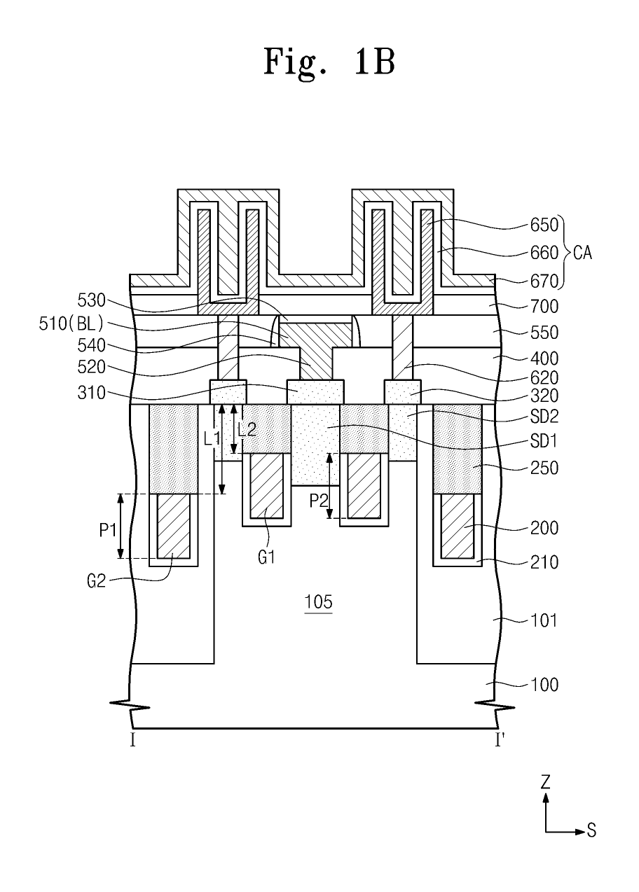

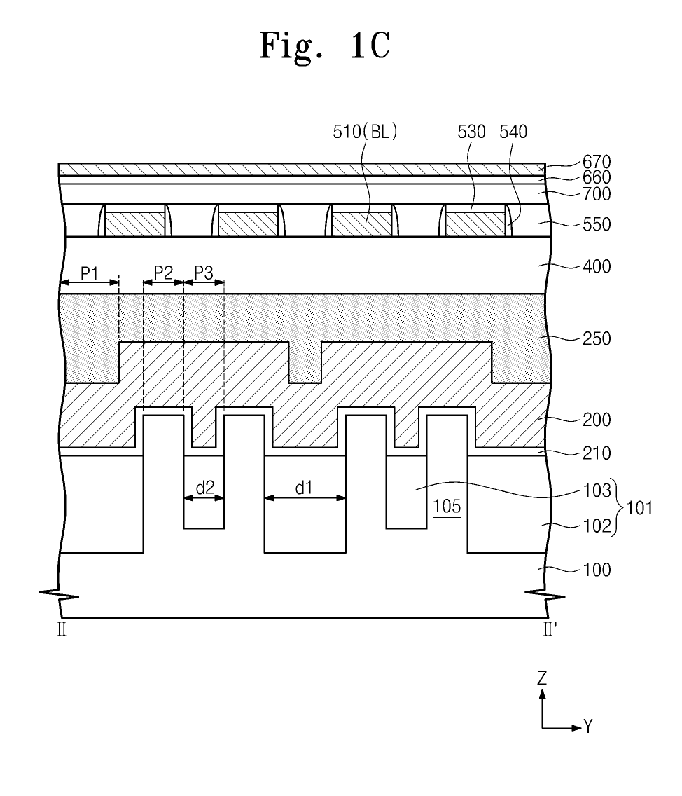

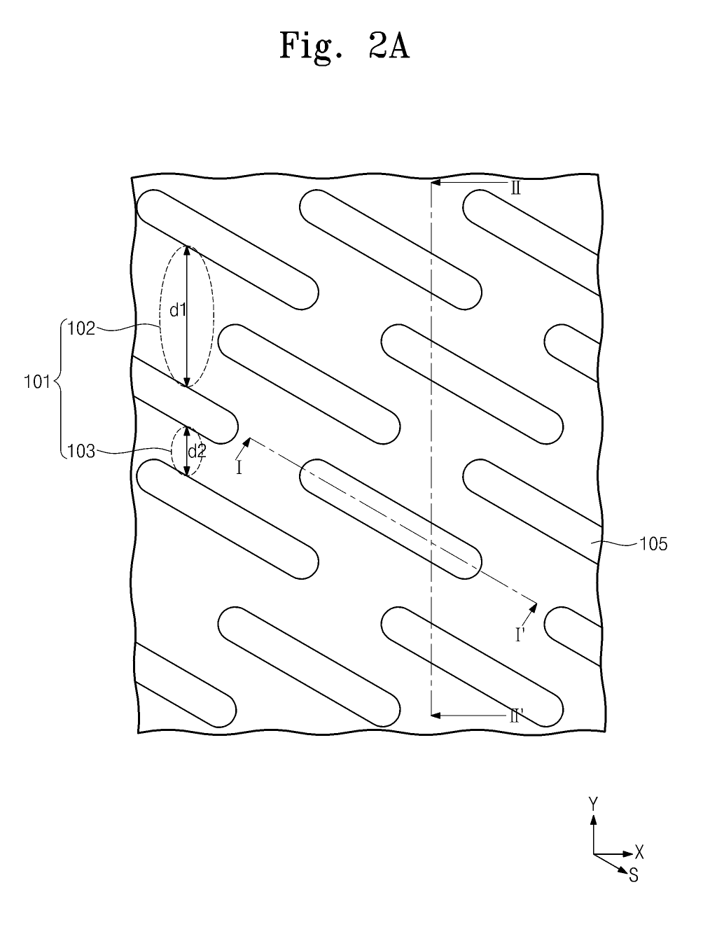

FIG. 1A is a plan view illustrating a semiconductor device according to example embodiments of the inventive concept. FIG. 1B is a sectional view taken along a line I-I′ of FIG. 1A, and FIG. 1C is a sectional view taken along a line II-II′ of FIG. 1A.

Referring to FIGS. 1A through 1C, a device isolation layer 101 may be provided on a substrate 100 to delimit active regions 105. The substrate 100 may be a semiconductor substrate, for example, a silicon wafer, a germanium wafer, a silicon-germanium wafer, or the like. Each of the active regions 105 may be shaped like a bar when viewed from a plan view and can extend along a longitudinal axis parallel to a third direction, or S direction, at an angle relative to a first direction, or X direction, and a second direction, or Y direction. Here, the first (X) and second (Y) directions may intersect.

A plurality of gate lines 200 may be provided in the substrate 100 that cross the active regions 105, when viewed from a plan view as shown in FIG. 1A. The gate lines 200 may extend along the second direction Y. The gate lines 200 may be positioned along the first direction X and be parallel each other. The gate lines 200 may be buried in the substrate 100. The gate lines 200 may include a conductive material. For example, the conductive material may be one of doped semiconductor materials, e.g., doped silicon, doped germanium, and so forth, conductive metal nitrides, e.g., titanium nitride, tantalum nitride, and so forth, metals, e.g., tungsten, titanium, tantalum, and so forth, metal-semiconductor compounds, e.g., tungsten silicide, cobalt silicide, titanium silicide, and so forth, or a combination thereof. At least some of the semiconductor device can extend along a fourth direction, or Z direction, which may be a direction orthogonal to the first to third directions. For example, as shown in FIG. 1B, the fourth (Z) direction is orthogonal to the third (S) direction, and as shown in FIG. 1C, the fourth direction (Z) is orthogonal to the second (Y) direction. In the Z-S section of FIG. 1B and the Z-Y section of FIG. 1C, gate isolation patterns 210 may be interposed between the gate lines 200 and the active regions 105 and between the gate lines 200 and the device isolation layer 101. The gate isolation patterns 210 may include an oxide layer, a nitride layer, and/or an oxynitride layer. First capping patterns 250 may be provided on the gate lines 200. A top surface of the first capping patterns 250 may be coplanar with that of the substrate 100. The first capping patterns 250 may include a silicon oxide layer, a silicon nitride layer, and/or a silicon oxynitride layer. In example embodiments as shown in FIG. 1B, a bottom surface of the first capping patterns 250 may be in contact with the top surface of the gate isolation patterns 210, and both side surfaces of the first capping patterns 250 may be in contact with the active regions 105 and/or the device isolation layer 101. In other example embodiments, the gate isolation patterns 210 may extend between the first capping patterns 250 and the active regions 105 and/or between the first capping patterns 250 and the device isolation layer 101. In this case, the first capping patterns 250 may include a silicon nitride layer, and the gate isolation patterns 210 may include a silicon oxide layer. Here, the gate isolation patterns 210 interposed between the first capping patterns 250 and the active regions 105 may serve as a buffer layer reducing a stress between the active regions 105 and the first capping patterns 250.

A first doped region SD1 may be provided in an active region 105 and can be adjacent a side surface of a gate line 200. A second doped region SD2 may be provided in the active region 105, and can be adjacent a side surface of another gate line 200, or at a side surface of the gate line 200 opposite the side surface at which the first doped region SD2 is positioned. In example embodiments, the first doped region SD1 may have a bottom surface deeper, or lower, than that of the second doped region SD2. In other example embodiments, the first doped region SD1 may be formed to have substantially the same depth as that of the second doped region SD2. The first and second doped regions SD 1 and SD2 may have a different conductivity type with respect to the substrate 100. For example, in the case where the substrate 100 is a P-type, the first and second doped regions SD1 and SD2 are an N-type.

Returning to FIG. 1A, the device isolation layer 101 may include a first region 102 and a second region 103 that cross the gate lines 200. A distance d1 between the active regions 105 adjacent to first region 102 may be greater than a distance d2 between the active regions 105 adjacent to second region 103. The distances d1 and d2 between the active regions 105 may be dimensions that are measured along the second direction Y. In example embodiments, since the distance d1 is greater than the distance d2, the device isolation layer 101 at the first region 102 may be formed or extend more deeply into the substrate 100 than the device isolation layer 101 at the second region 103. In other example embodiments, the device isolation layers 101 at the first and second regions 102 and 103, respectively, may be formed to have substantially the same depth.

The gate lines 200 may each include a first portion P1 on the first region 102, a second portion P2 on an active region 105, and a third portion P3 on the second region 103. A top surface of the first portion P1 may be lower than that of the second portion P2 and that of the third portion P3. Top surfaces of the second portion P2 and the third portion P3 may be coplanar with each other. A bottom surface of the first portion P1 may be lower than that of the second portion P2 and be substantially coplanar with that of the third portion P3. The top surface of the first portion P1 may be higher than the bottom surface of the second portion P2. Due to the vertical levels of the top and bottom surfaces of the first, second, and third portions P1, P2, and P3 relative to each other, the gate lines 200 may have concavo-convex surfaces.

One of the gate lines (hereinafter, a first gate line G1) may be spaced apart from another of the gate lines (hereinafter, a second gate line G2) with the second doped region SD2 interposed therebetween. The second gate line G2 may be separated from the second doped region SD2 by the device isolation layer 101. A voltage applied to the second doped region SD2 may be capacitively coupled to the second gate line G2, thereby deteriorating a refresh property of the semiconductor device. According to example embodiments of the inventive concept, the top surface of the first portion P1 of the second gate line G2 may be lower than the top surface of the second portion P2 of the first gate line G1. The top surface of the device isolation layer 101 and the top surface of the active region 105 at which the first gate line is positioned, more specifically, the doped regions SD1, SD2, can extend along a same axis, for example, in the S direction. Thus, a distance L1 between the top surface of the first portion P1 of the second gate line G2 and the top surface of the active region 105 may be greater than a distance L2 between the top surface of the second portion P2 of the first gate line G1 and the top surface of the active region 105. Accordingly, it is possible to decrease a coupling effect on the second gate line G2 by applying a voltage to the second doped region SD2 and to thereby improve a refresh property of the semiconductor device.

First pads 310 and second pads 320 may be provided on the substrate 100 and be connected to the first doped region SD1 and the second doped region SD2, respectively. The first pads 310 and the second pads 320 may include a conductive material such as doped polysilicon or metal. The first pad 310 may have a width greater than the first doped region SD1. The second pad 320 may have a width greater than the second region SD2. This configuration can facilitate a subsequent process of forming contacts on the pads 310 and 320, respectively, and reduce contact resistance between the contacts and the pads.

A first interlayered insulating layer 400 may be provided on the pads 310 and 320. The first interlayered insulating layer 400 may include a silicon oxide layer, a silicon nitride layer, a silicon oxynitride layer, or the like. Bit lines BL and 510 may be provided on the first interlayered insulating layer 400. The bit lines BL and 510 may be provided in a second interlayered insulating layer 550 that is formed on the first interlayered insulating layer 400. The second interlayered insulating layer 550 may include a silicon oxide layer, a silicon nitride layer, a silicon oxynitride layer, or the like. The bit lines BL and 510 may be connected to bit line contacts 520, which may be connected to the first pads 310 through the first interlayered insulating layer 400. The bit lines BL and 510 and the bit line contacts 520 may include at least one of doped semiconductor materials, e.g., doped silicon, doped germanium, and so forth, conductive metal nitrides, e.g., titanium nitride, tantalum nitride, and so forth, metals, e.g., tungsten, titanium, tantalum, and so forth, and/or metal-semiconductor compounds, e.g., tungsten silicide, cobalt silicide, titanium silicide, and so forth. Second capping patterns 530 may be provided on the bit lines BL and 510. The sidewalls of each of the bit lines BL and 510 may be covered with insulating spacers 540. The second capping patterns 530 and the insulating spacers 540 may include at least one of a silicon nitride layer, a silicon oxide layer, or a silicon oxynitride layer.

Buried contacts 620 may be provided on the substrate 100 and be connected to the second pads 320 through the first and second interlayered insulating layer 400 and 550. The buried contacts 620 may include a conductive material such as doped silicon or a metal. Data storing elements may be provided on the second interlayered insulating layer 550 and be connected to the buried contacts 620. In example embodiments, the data storing elements may be capacitors CA. The capacitor CA may include a lower electrode 650, an upper electrode 670, and a dielectric film 660 interposed between the lower electrode 650 and the upper electrode 670. The lower electrode 650 may be shaped like a bottom-closed cylinder. The upper electrode 670 may be formed to cover a plurality of the lower electrodes 650, thereby serving as a common electrode. The lower electrode 650 and the upper electrode 670 may include at least one of doped silicon, metals, or metal compounds. A supporting layer 700 may be disposed between the upper electrode 670 and the second interlayered insulating layer 550. The supporting layer 700 may be disposed on outer sidewalls of the lower electrodes 650 to provide support for bottom regions of the lower electrodes 650, for example, prevent the lower electrodes 650 from damage due to falling or the like. The supporting layer 700 may include an insulating material. The dielectric film 660 may extend laterally to be interposed between the supporting layer 700 and the upper electrode 670.

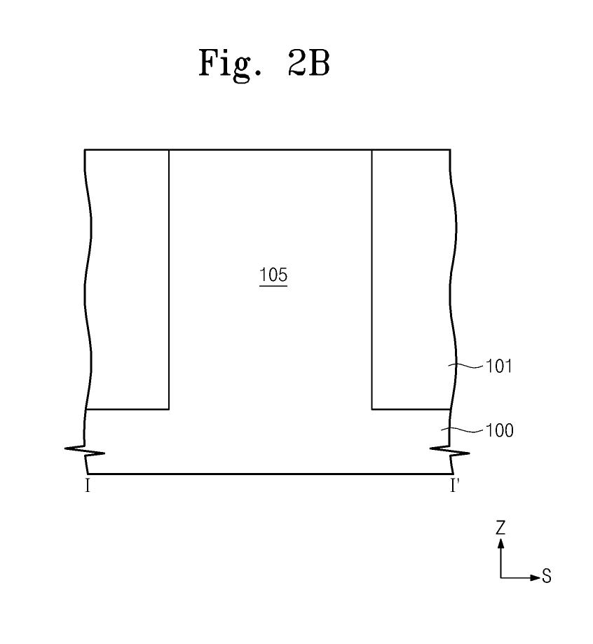

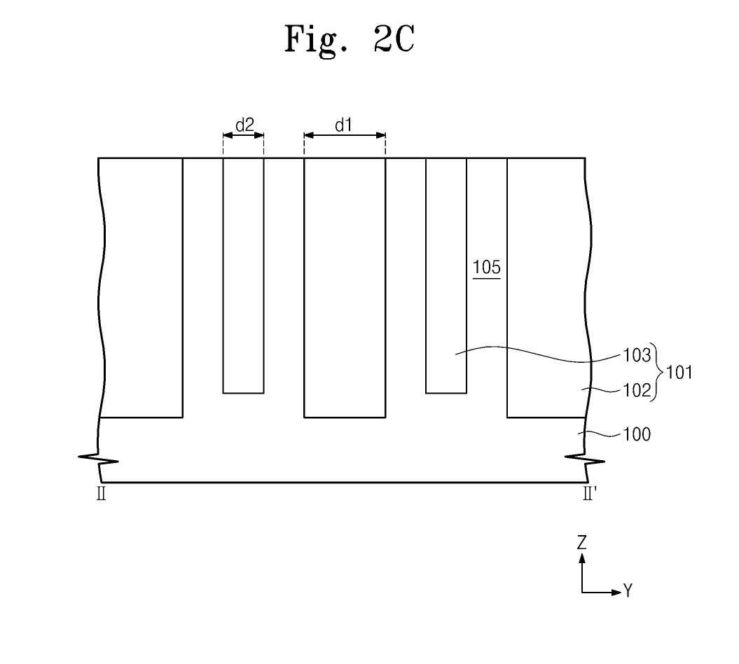

FIGS. 2A through 9A are plan views illustrating a method of fabricating a semiconductor device according to example embodiments of the inventive concept. FIGS. 2B through 9B are sectional views taken along lines I-I′ of FIGS. 2A through 9A, respectively. FIGS. 2C through 9C are sectional views taken along lines of FIGS. 2A through 9A, respectively.

Referring to FIGS. 2A through 2C, a device isolation layer 101 may be formed in a substrate 100 to delimit active regions 105. The device isolation layer 101 may be formed using, for example, a shallow trench isolation (STI) technique. The device isolation layer 101 may include at least one of a silicon nitride layer, a silicon oxide layer, and/or a silicon oxynitride layer. The device isolation layer 101 may include a first region 102 and a second region 103 formed to cross gate lines that will be described below. A distance d1 between the active regions 105 adjacent to the first region 102 may be greater than a distance d2 between the active regions 105 adjacent to the second region 103. The distances d1 and d2 between the active regions 105 may be dimensions that are measured along the second direction Y. In example embodiments, since the distance d1 is greater than the distance d2, a device isolation layer of the first region 102 may be formed to extend more deeply into the substrate 100 than a device isolation layer of the second region 103, for example, shown in FIGS. 1C and 2C. In other example embodiments, the device isolation layers of the first and second regions 102 and 103 may be formed to have substantially the same depth.

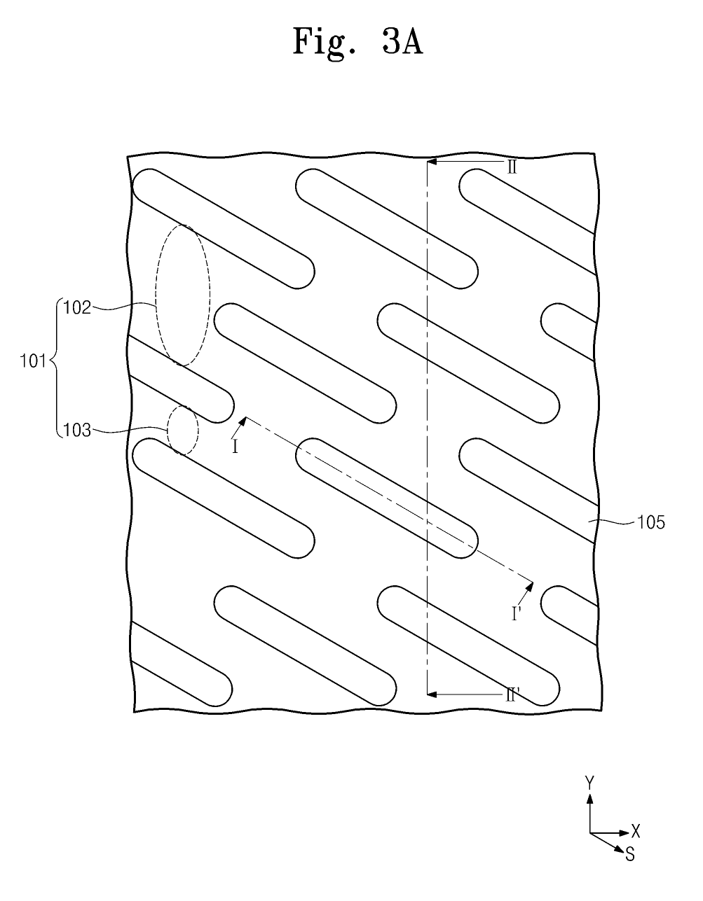

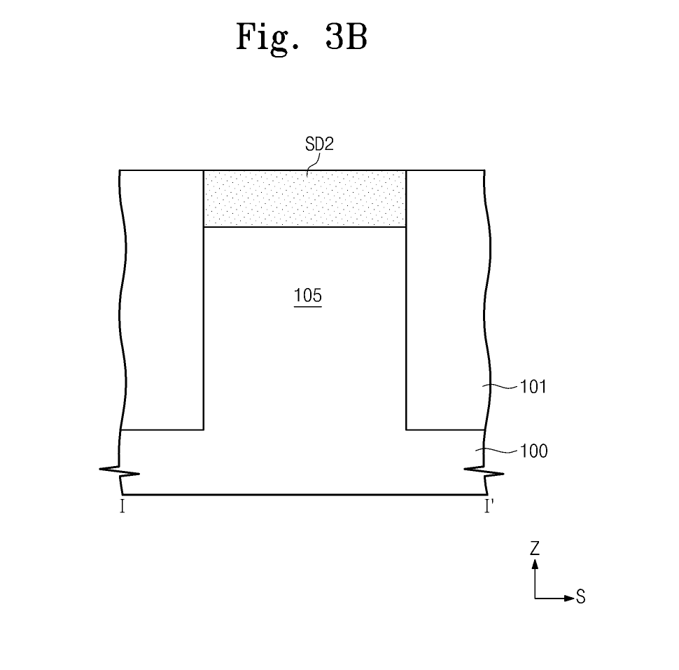

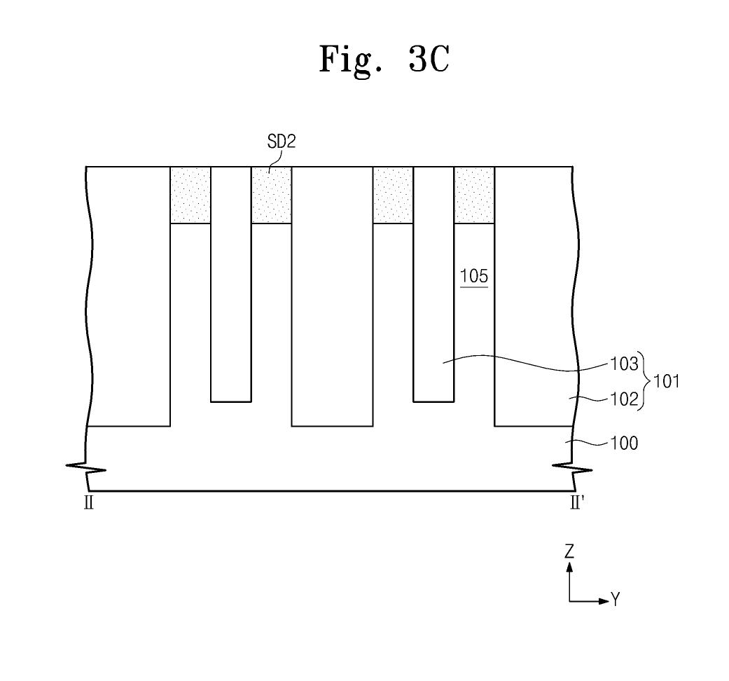

Referring to FIGS. 3A through 3C, a second doped region SD2 may be formed in the active region 105 of the substrate 100. The second doped region SD2 may be formed by an ion implantation process. In example embodiments, the second doped region SD2 may be an n-type doped region.

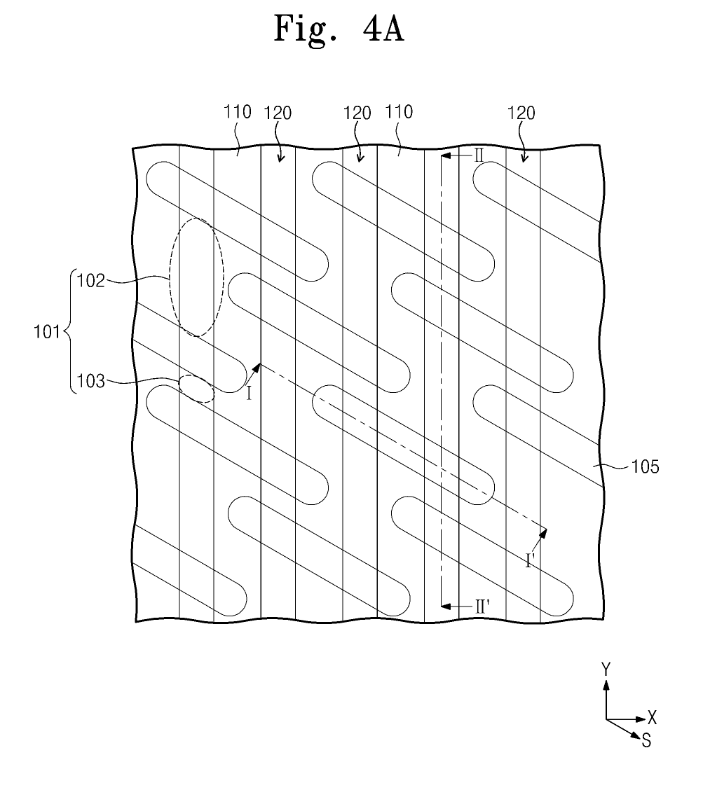

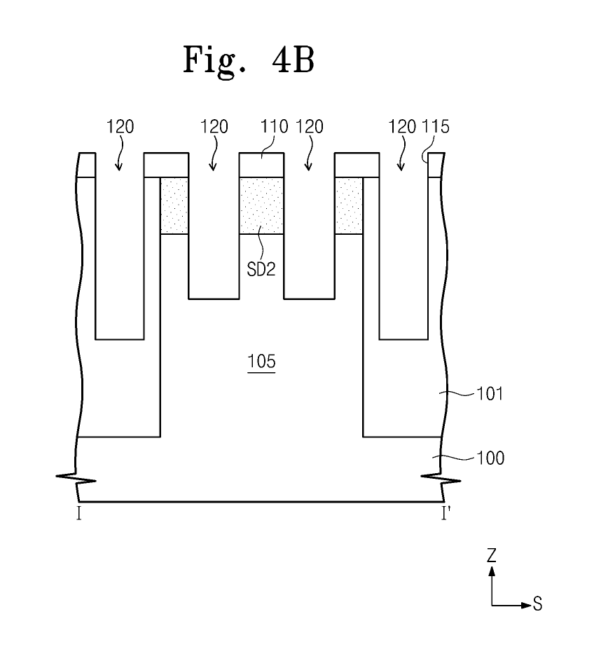

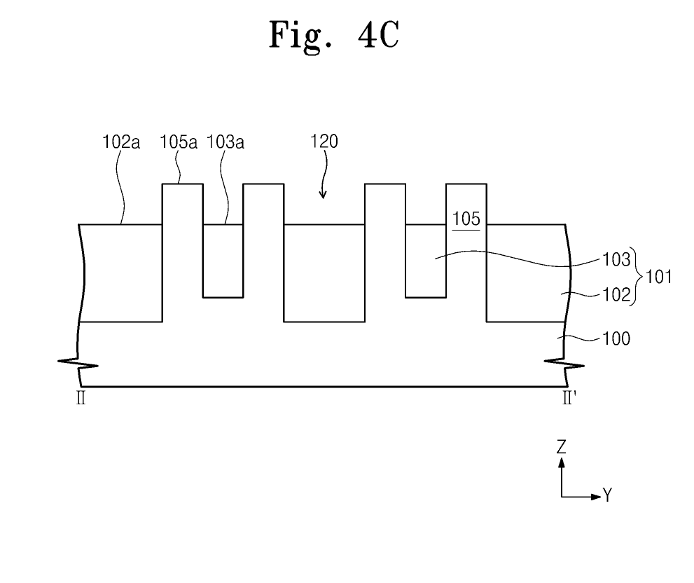

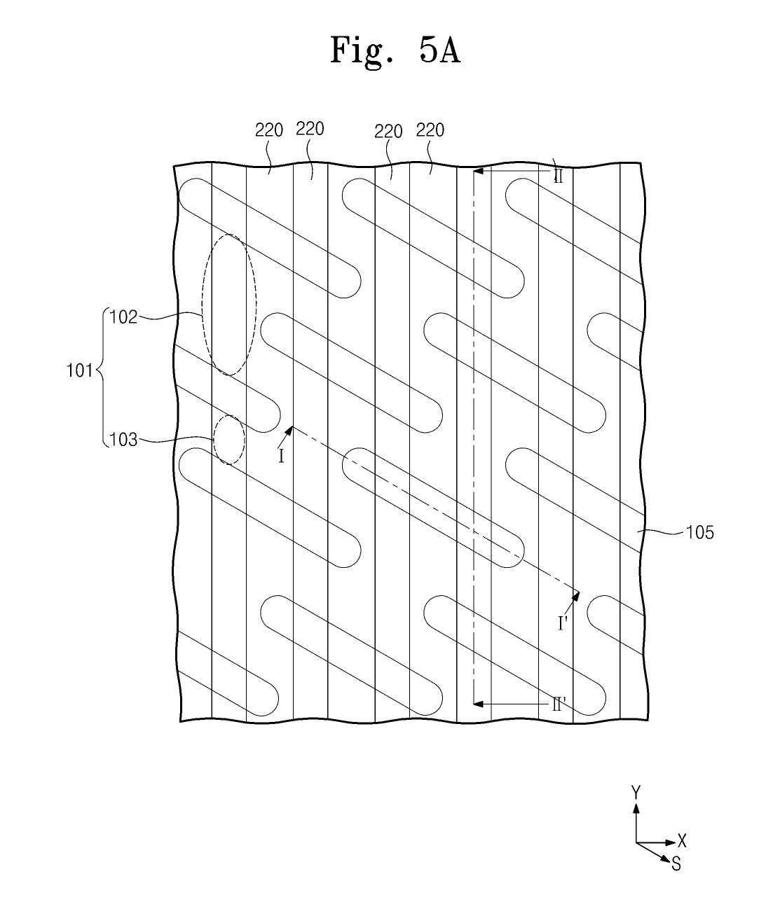

Referring to FIGS. 4A through 4C, first mask patterns 110 may be formed on the substrate 100. The first mask patterns 110 may be define regions having first openings 115, at which gate lines can be provided. The first mask patterns 110 may be a hard mask pattern, for example, formed of silicon nitride or the like, or may be formed as a photoresist pattern. The substrate 100 and the device isolation layer 101 may be etched using the first mask patterns 110 as an etch mask to form line-shaped trenches 120 extending along the second direction Y. The trenches 120 may be formed to have a bottom surface exposing the first region 102, the active region 105, and the second region 103. Because of a difference in etch selectivity in the etching process for forming the trenches 120, the first region 102 and the second region 103 may be etched deeper than the active region 105. For example, as shown in FIG. 4C, a top surface 102a of the first region 102 and a top surface 103a of the second region 103 may be lower than a top surface 105a of the active region 105 exposed by the trenches 120. Accordingly, the trenches 120 may be formed to have a concavo-convex bottom surface.

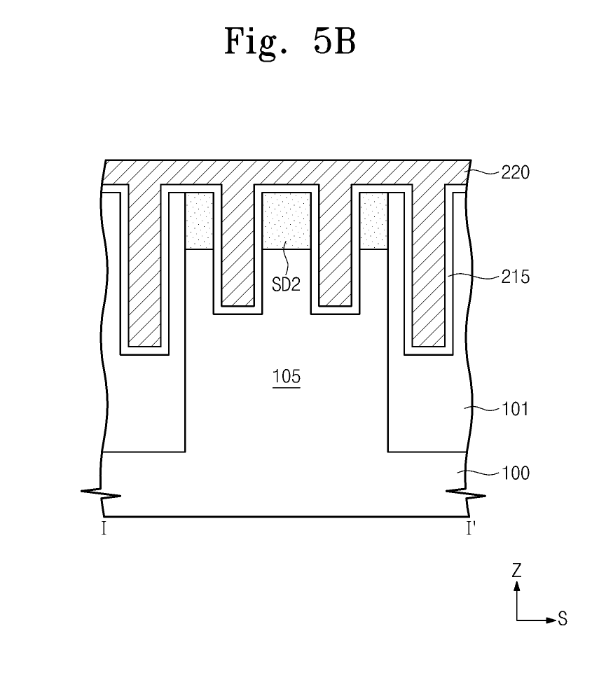

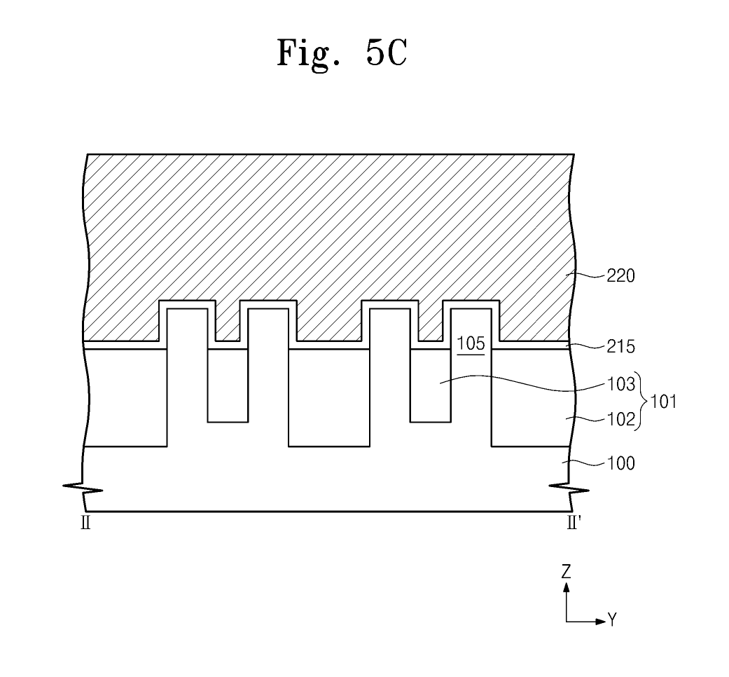

Referring to FIGS. 5A through 5C, the first mask patterns 110 may be removed. In the case where a photoresist pattern is used for the first mask patterns 110, the first mask patterns 110 may be removed by an ashing process or the like. In the case where a mask pattern for example, formed of a silicon nitride layer, is used for the first mask patterns 110, the first mask patterns 110 may be removed by a cleaning process using phosphoric acid. An insulating layer 215 may be formed on the substrate 100 provided with the trenches 120. The insulating layer 215 may be formed by a thermal oxidation process, an atomic layer deposition process or a chemical vapor deposition process. In example embodiments, the insulating layer 215 may include a silicon oxide layer. A first conductive layer 220 may be formed on the substrate 100 provided with the insulating layer 215. The first conductive layer 220 may be formed using a chemical vapor deposition process. The first conductive layer 220 may include a conductive material. For example, the conductive material may be one of doped semiconductor materials, e.g., doped silicon, doped germanium, and so forth, conductive metal nitrides, e.g., titanium nitride, tantalum nitride, and so forth, metals, e.g., tungsten, titanium, tantalum, and so forth, and/or metal-semiconductor compounds, tungsten silicide, cobalt silicide, titanium silicide, and so forth.

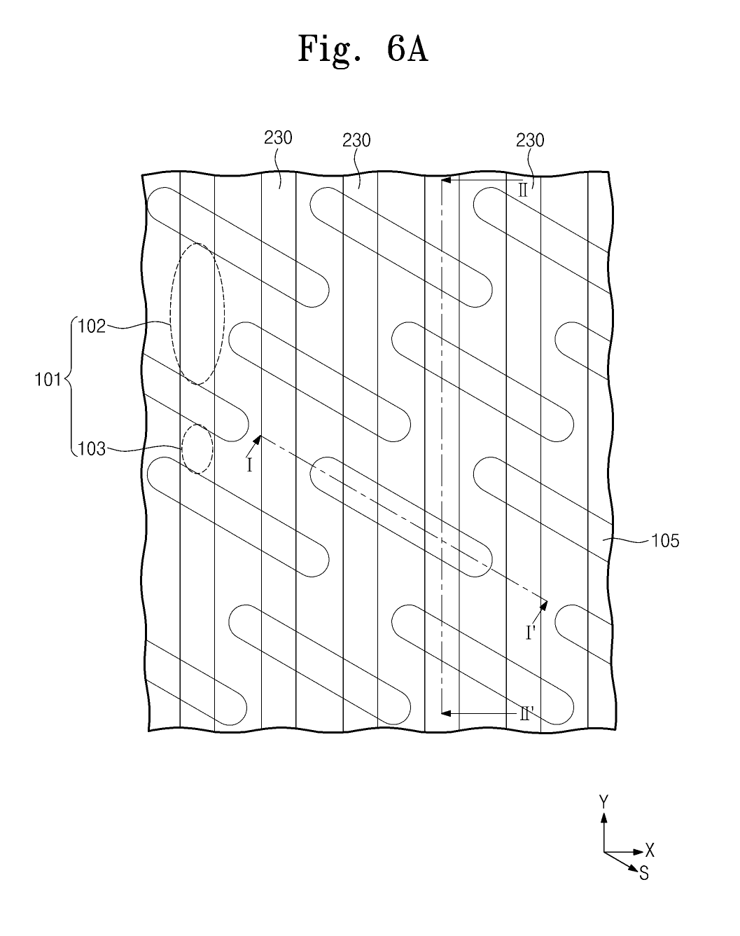

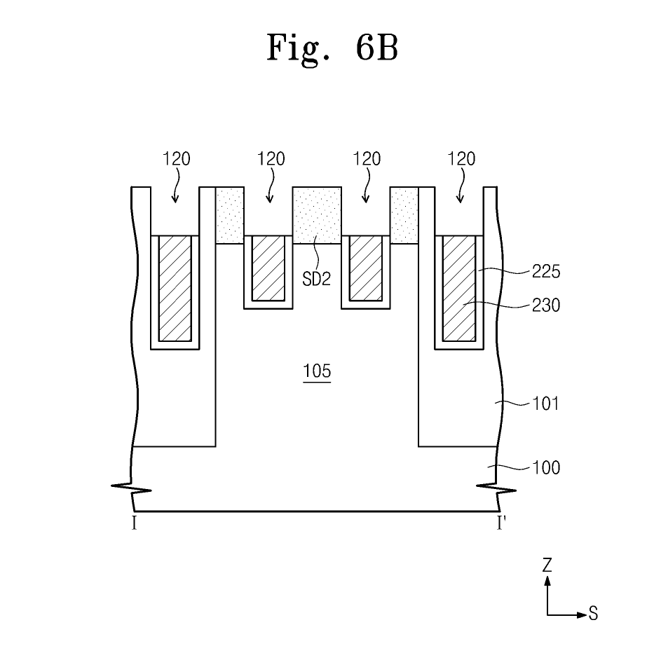

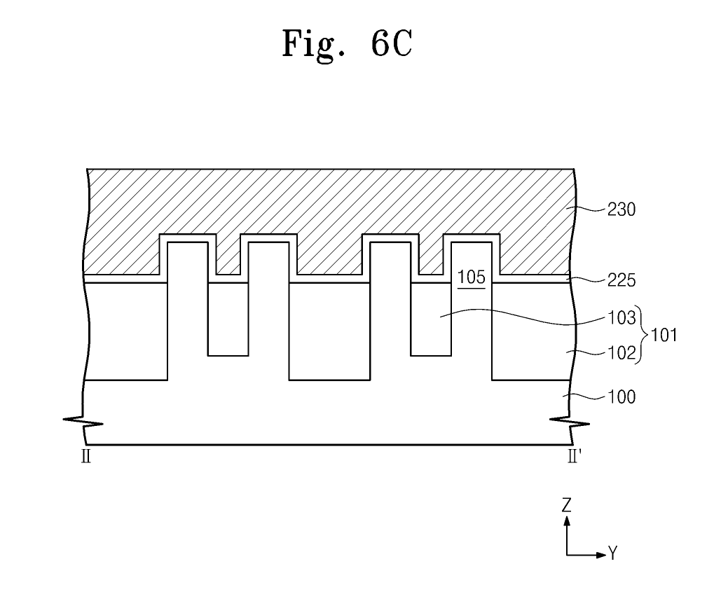

Referring to FIGS. 6A through 6C, the first conductive layer 220 may be etched to form one or more conductive patterns 230. The etching process may be performed until a thickness of the first conductive layer 220 in the trenches 120 is at a desired thickness. As the etching process continues, an upper portion of the insulating layer 215 may be exposed by the conductive patterns 230 and removed. Accordingly, isolation patterns 225 may be formed between the conductive patterns 230 and the active regions 105 and/or between the conductive patterns 230 and device isolation layer 101. In addition, top surfaces of the device isolation layer 101 and active regions 105 may be exposed by the etching process.

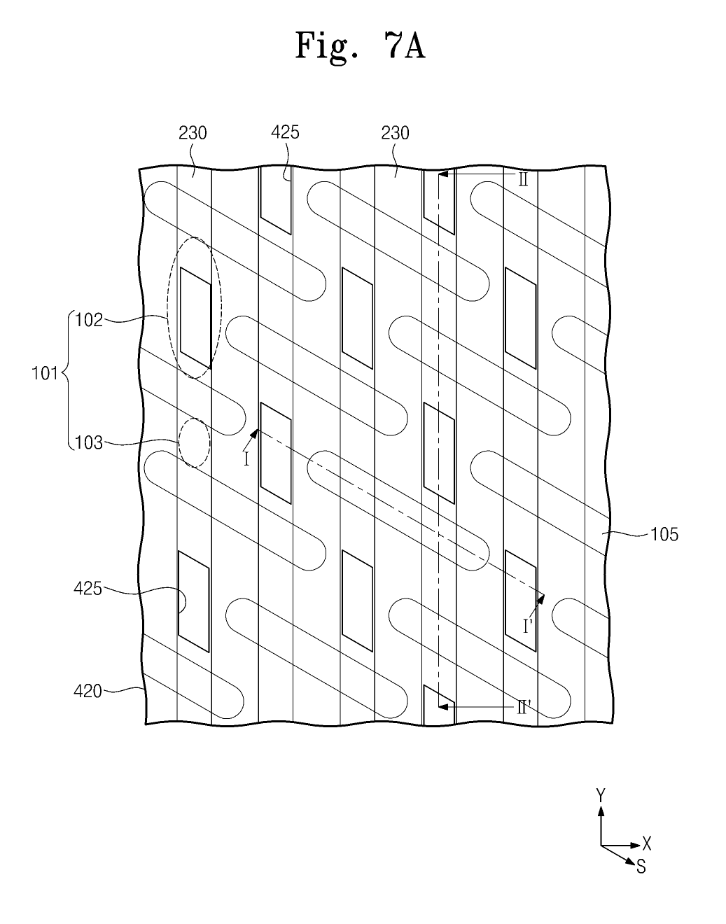

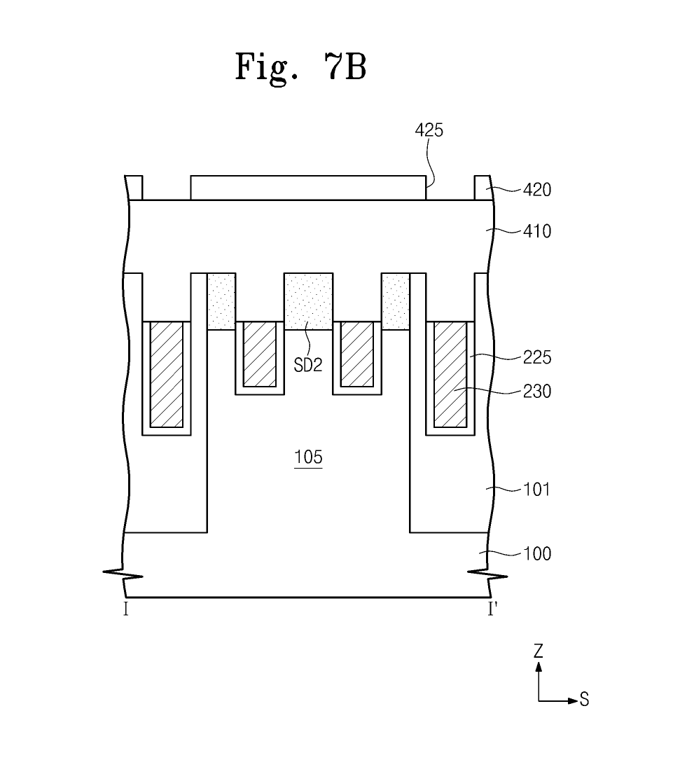

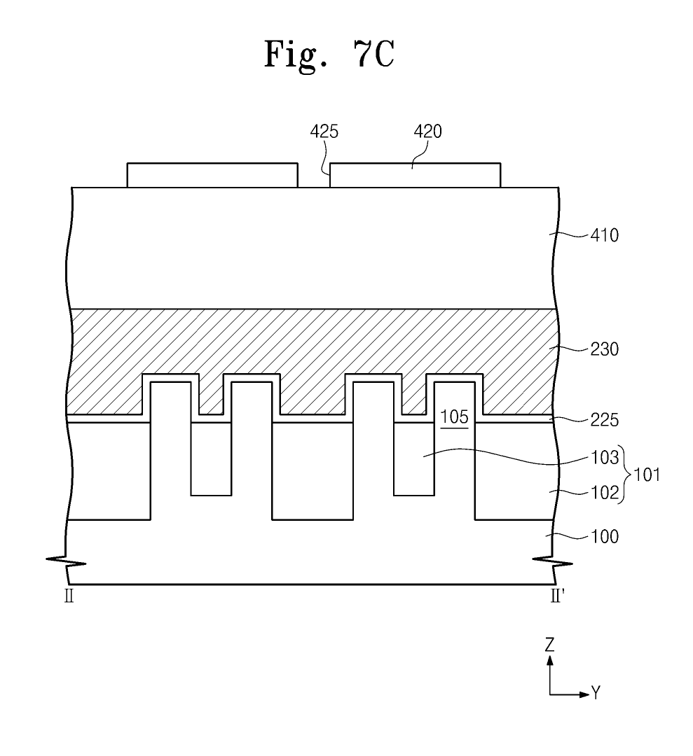

Referring to FIGS. 7A through 7C, a mask layer 410 may be formed on the substrate 100. In example embodiments, the mask layer 410 may be formed using a chemical vapor deposition process. The mask layer 410 may include a layer of plasma enhanced (PE)-SiON, SOH, and/or carbon-containing oxide. For example, the mask layer 410 may include a SOH layer on the substrate 100 and a PE-SiON layer on the SOH layer. A second mask pattern 420 may optionally be formed on the mask layer 410. The second mask pattern 420 may have a plurality of second openings 425. The second openings 425 may overlap the first regions 102. In example embodiments, the second mask pattern 420 may be a photoresist pattern.

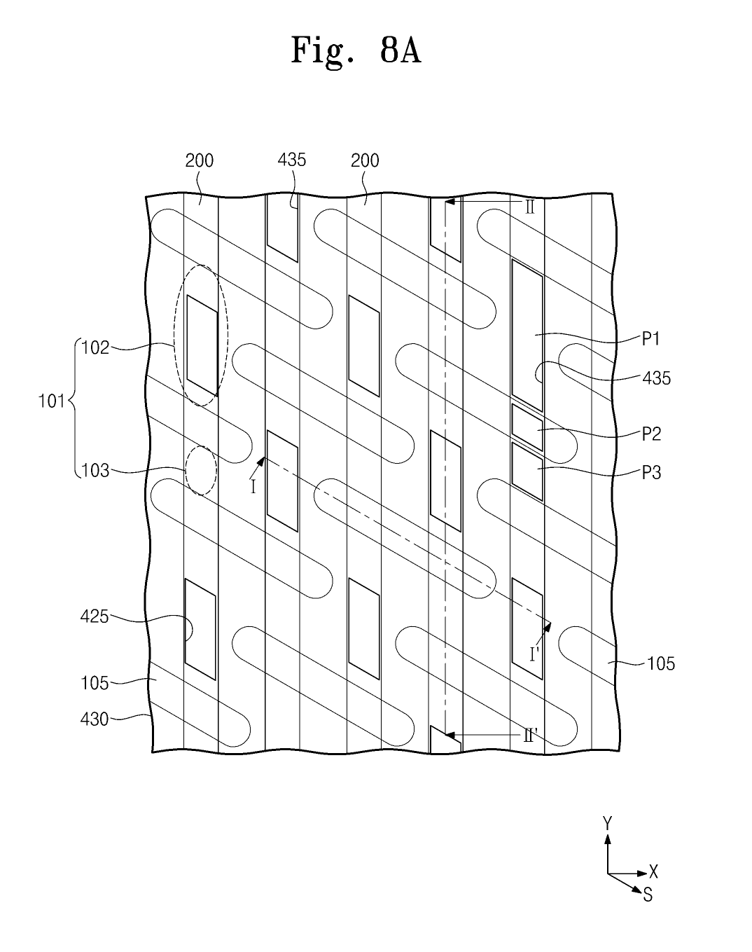

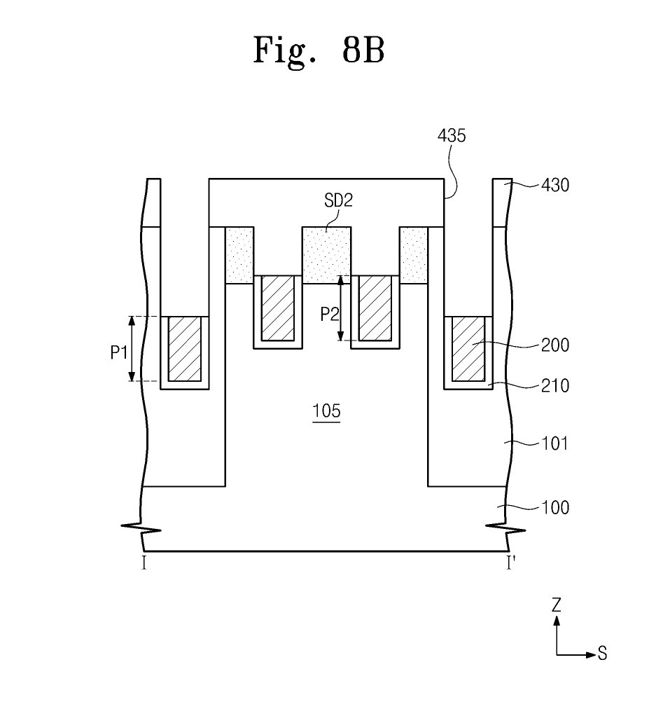

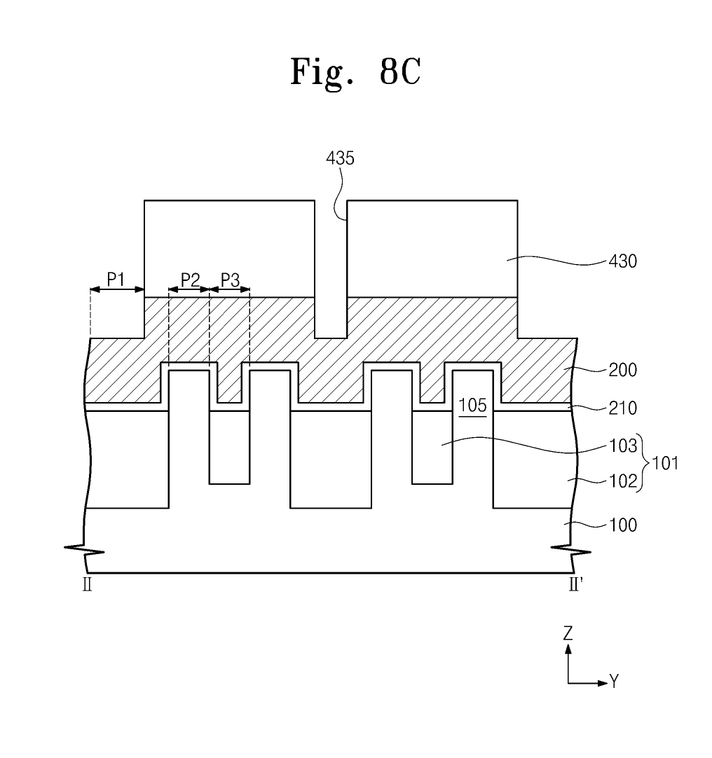

Referring to FIGS. 8A through 8C, the mask layer 410 may be etched using the second mask patterns 420 as an etch mask, thereby forming a third mask pattern 430 having one or more third openings 435. The second opening 425 and the third opening 435 may be formed to have substantially the same or similar dimensions, for example, length, width, and so on. The conductive patterns 230 on the first region 102 may be etched using the third mask patterns 430 as an etch mask to form gate lines 200. The isolation patterns 225 may be partially etched using the process of etching the conductive patterns 230 to form gate isolation patterns 210. Each of the gate lines 200 may include a first portion P1 on the first region 102, a second portion P2 on the active regions 105, and a third portion P3 on the second region 103. As the result of the etching process, a top surface of the first portion P1 may be lower than that of the second portion P2 and the third portion P3. Top surfaces of the second portion P2 and the third portion P3 may be coplanar with respect to each other. Due to these differences in vertical levels of the top surfaces of the first, second, and third portions P1, P2, and P3, respectively, the gate lines 200 may have concavo-convex top surfaces. In example embodiments, the top surface of the first portion P1 may be higher than a bottom surface of the second portion P2.

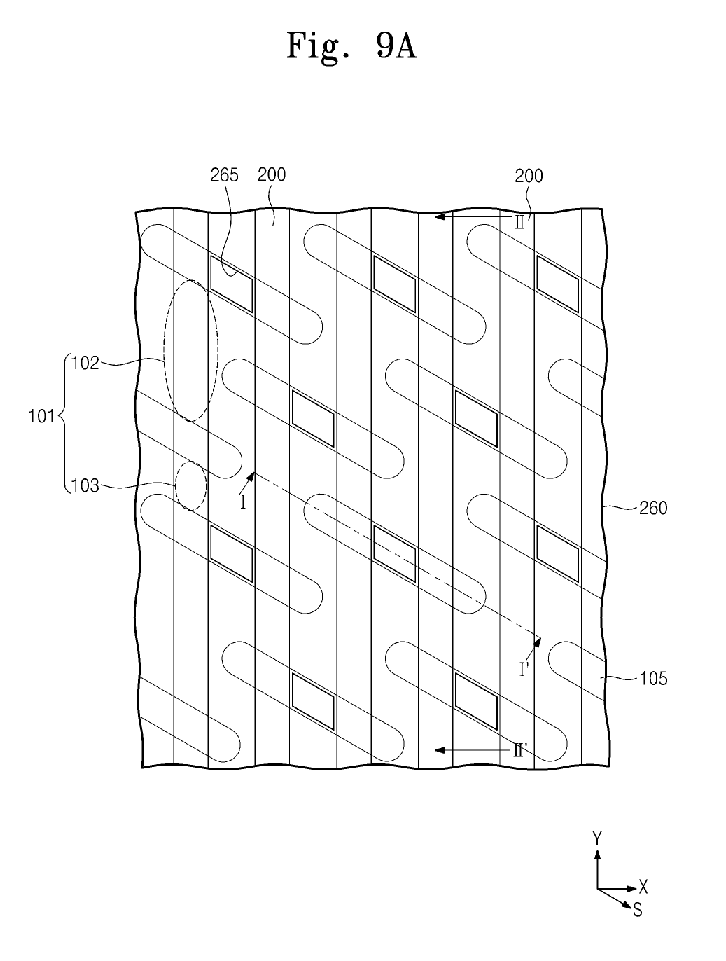

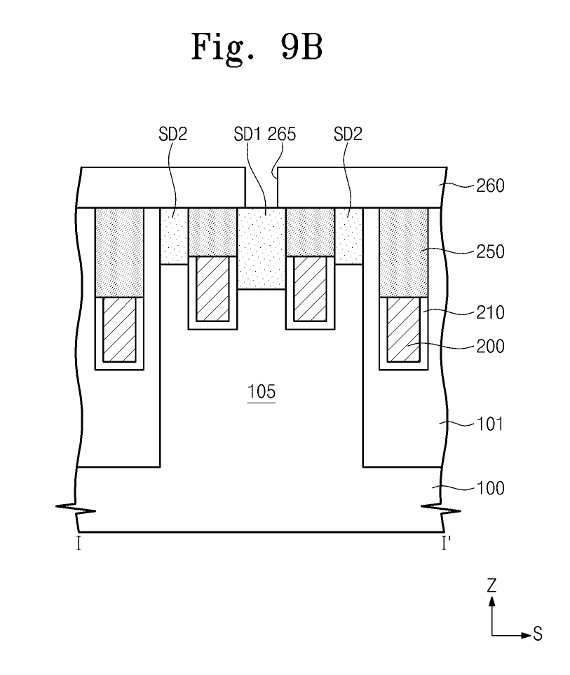

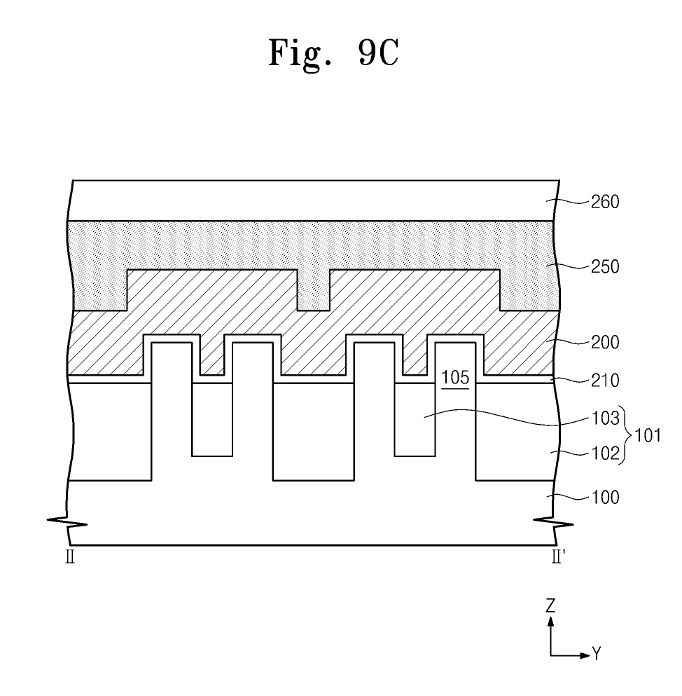

Referring to FIGS. 9A through 9C, the third mask patterns 430 may be removed. For example, the third mask patterns 430 may be removed by a cleaning process using phosphoric acid. A first capping layer may be formed on the substrate 100 and then be etched using a planarization process to form first capping patterns 250 provided in the trenches 120. The first capping patterns 250 may include at least one of a silicon nitride layer, a silicon oxide layer, or a silicon oxynitride layer. Fourth mask patterns 260 may be formed on the substrate 100 to have fourth openings 265 defining first doped regions. For example, the fourth mask patterns 260 may be a photoresist pattern. The fourth mask patterns 260 may be used as a mask in an ion implantation process for forming the first doped regions. For example, an ion implantation process may be performed on the substrate 100 exposed by the fourth mask patterns 260 to form first doped regions SD1 in the active region 105 between a pair of the gate lines 200 adjacent to each other. The first doped regions SD1 may be formed to have the same conductivity type, e.g., an n-type conductivity type, as the second doped region SD2. The first doped region SD1 may extend into the substrate 100 more deeply than the second doped region SD2. After the ion implantation process, the fourth mask patterns 260 may be removed by an ashing process or the like.

Referring back to FIGS. 1A through 1C, a doped polysilicon layer, a doped single crystalline silicon layer, or a conductive layer may be sequentially formed on the substrate 100 and then patterned to form first pads 310 and second pads 320. The first pads 310 may be connected to the first doped regions SD1, respectively, and the second pads 320 may be connected to the second doped regions SD2, respectively. In embodiments where the first and second pads 310 and 320 include the doped polysilicon layer or the single crystalline silicon layer, the first and second pads 310 and 320 may be doped with impurities having the same conductivity type as the first and second doped regions SD1 and SD2, respectively.

A first interlayered insulating layer 400 may be formed on the first and second pads 310 and 320. In example embodiments, the first interlayered insulating layer 400 may be formed using a chemical vapor deposition process or the like. The first interlayered insulating layer 400 may include at least one of a silicon oxide layer, a silicon nitride layer, or a silicon oxynitride layer. A portion of the first interlayered insulating layer 400 may be patterned to form contact holes delimiting bit line contacts. A second conductive layer may be formed on the first interlayered insulating layer 400. The second conductive layer may be formed to fill the contact holes. For example, the second conductive layer may include a conductive material such as metals and/or doped semiconductor materials. A second capping layer may be formed on the second conductive layer. For example, the second capping layer may include at least one of a silicon nitride layer, a silicon oxide layer, a silicon oxynitride layer, or the like. The second capping layer and the second conductive layer may be patterned to form bit lines 510 and second capping patterns 530 provided thereon. Bit line contacts 520 may be formed in the contact holes. An insulating spacer layer may be conformally deposited on the first interlayered insulating layer 400 and then be anisotropically etched to form insulating spacers 540 covering sidewalls of each of the bit lines 510. The insulating spacers 540 may include at least one of a silicon nitride layer, a silicon oxide layer, a silicon oxynitride layer, or the like.

A second interlayered insulating layer 550 may be formed on the first interlayered insulating layer 400 and then be etched using a planarization process to expose top surfaces of the second capping patterns 530. Thereafter, buried contacts 620 may be connected to the second pads 320 through the second interlayered insulating layer 550 and the first interlayered insulating layer 400. The buried contacts 620 may include a conductive material such as doped silicon or metals. A supporting layer 700 may be formed on the second interlayered insulating layer 550. The supporting layer 700 may include at least one of a silicon oxide layer, a silicon nitride layer, a silicon oxynitride layer, or the like. The supporting layer 700 may be formed using a chemical vapor deposition process or the like. Lower electrodes 650 may be connected to the buried contacts 620, respectively, through the supporting layer 700. Each of the lower electrodes 650 may be formed to have a bottom-closed cylindrical structure. A dielectric film 660 may be formed to conformally cover the lower electrodes 650 and an upper electrode 670 may be formed to cover the lower electrodes 650 covered with the dielectric film 660, thereby completing the formation of capacitors CA. The lower electrodes 650 and the upper electrode 670 may include at least one of a doped silicon layer, metal layers, metal compounds, or the like. As a result, the semiconductor device according to example embodiments of the inventive concept may be completed.

According to example embodiments of the inventive concept, the gate line may be separated from the second doped region by the device isolation layer. A gate line adjacent to the second doped region can be suppressed or prevented from being capacitively coupled by a voltage applied the second doped region, which can improve a refresh property of the semiconductor device.

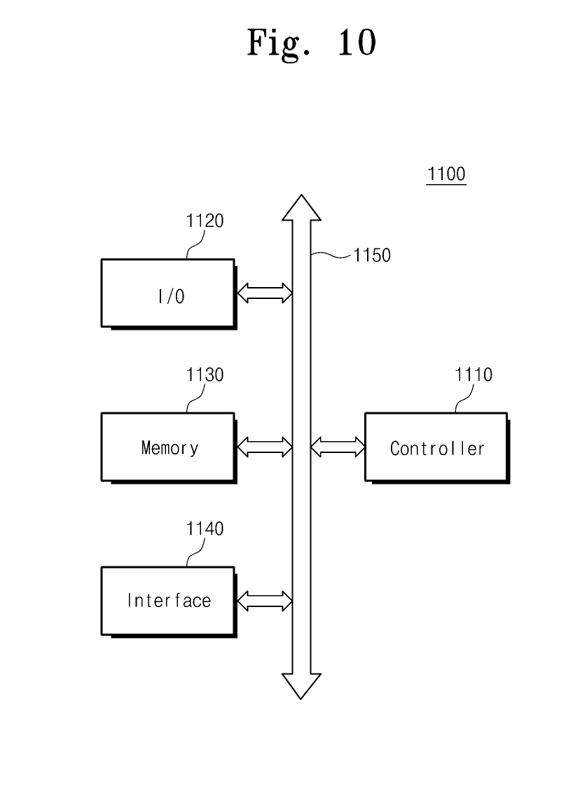

FIG. 10 is a schematic block diagram illustrating an example of an electronic system 1100 including semiconductor devices according to embodiments of the inventive concept.

Referring to FIG. 10, an electronic system 1100 according to an embodiment of the inventive concept may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150. The data bus 1150 may provide a conductive path through which electrical signals are transmitted.

The controller 1110 may include, e.g., at least one of a microprocessor, a digital signal processor, a microcontroller, or another logic device. The other logic device may have a similar function to any one of the microprocessor, the digital signal processor, and the microcontroller. The I/O unit 1120 may include, e.g., a keypad, a keyboard, and/or a display unit. The memory device 1130 may store data and/or commands. The memory device 1130 may include at least one of the semiconductor devices according to the embodiments described above. The memory device 1130 may further include other types of semiconductor devices, which are different from the semiconductor devices described above. For example, the memory device 1130 may further include a non-volatile memory device, e.g., a flash memory device, a magnetic memory device, a phase change memory device, etc., and/or a static random access memory (SRAM) device. The interface unit 1140 may transmit electrical data to a communication network or may receive electrical data from a communication network. The interface unit 1140 may operate by wireless, cable, or other transmission elements. For example, the interface unit 1140 may include an antenna for wireless communication or a transceiver for cable communication. Although not shown in the drawings, the electronic system 1100 may further include a fast DRAM device and/or a fast SRAM device, which acts as a cache memory for improving an operation of the controller 1110.

The electronic system 1100 may be applied to electronic devices such as a personal digital assistant (PDA), a portable computer, a web tablet, a wireless phone, a mobile phone, a digital music player, a memory card, or other electronic products. The other electronic products may receive or transmit information data by wireless communication.

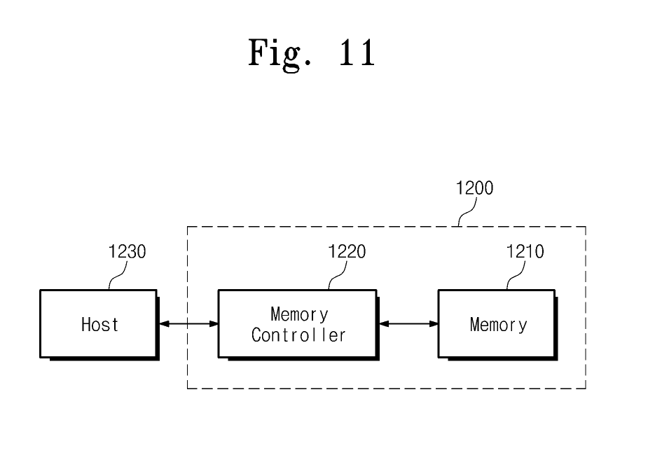

FIG. 11 is a schematic block diagram illustrating an example of a memory card 1200 including semiconductor devices according to embodiments of the inventive concept.

Referring to FIG. 11, a memory card 1200 according to an embodiment of the inventive concept may include a memory device 1210. The memory device 1210 may include at least one of the semiconductor devices according to the embodiments mentioned above. In other embodiments, the memory device 1210 may further include other types of semiconductor devices, which may be different from the semiconductor devices according to the embodiments described above. For example, the memory device 1210 may further include a non-volatile memory device, e.g., a flash memory device, a magnetic memory device, a phase change memory device, etc., and/or a static random access memory (SRAM) device. The memory card 1200 may include a memory controller 1220 that controls data communication between a host 1230 and the memory device 1210.

Accordingly, embodiments of the inventive concept can provide for an improved refresh property of a semiconductor device.

While example embodiments of the inventive concepts have been particularly shown and described, it will be understood by one of ordinary skill in the art that variations in form and detail may be made therein without departing from the spirit and scope of the attached claims.

1. A semiconductor device, comprising:
a substrate;
a device isolation layer defining one or more active regions at the substrate; and
one or more gate lines buried in the substrate, the gate lines crossing the active regions, wherein each of the gate lines comprises:
a first portion on the device isolation layer; and
a second portion on an active region of the active regions, and
wherein a top surface of the first portion is lower than a top surface of the second portion.

2. The device of claim 1, wherein a bottom surface of the first portion is lower than a bottom surface of the second portion.

3. The device of claim 1, wherein the top surface of the first portion is higher than a bottom surface of the second portion.

4. The device of claim 1, wherein the device isolation layer comprises a first region and a second region crossing the gate lines, wherein a distance between active regions of the one or more active regions adjacent to the first region is greater than a distance between active regions of the one or more active regions adjacent to the second region, and wherein the first portion is positioned on the first region.

5. The device of claim 4, wherein the gate lines further comprise a third portion positioned on the second region, and wherein the top surface of the first portion is lower than a top surface of the third portion.

6. The device of claim 5, wherein a bottom surface of the first portion is substantially coplanar with a bottom surface of the third portion.

7. The device of claim 1, further comprising a doped region formed in each of the active regions, wherein the doped region comprises a first doped region between the gate lines and a second doped region between the gate lines and the device isolation layer.

8. The device of claim 7, wherein the first doped region extends into the substrate having a depth that is greater than a depth of the second doped region.

9. The device of claim 7, wherein the gate lines comprise a first gate line buried in the active regions and a second gate line buried in the device isolation layer, and wherein a distance from a top surface of the second doped region to a top surface of the first portion of the second gate line is greater than a distance from a top surface of the second doped region to a top surface of the second portion of the first gate line.

10. The device of claim 9, wherein the second gate line is separated from the second doped region by the device isolation layer.

11. The device of claim 7, further comprising:
bit lines provided on the substrate and connected to the first doped region; and
a capacitor on the substrate and coupled to the second doped region.

12-15. (canceled)

16. A semiconductor device, comprising:
a substrate;
a device isolation layer defining a plurality of active regions at the substrate; and
first and second gate lines in the substrate that cross the active regions, wherein each of the first and second gate lines comprises:
a first portion on the device isolation layer; and
a second portion on an active region of the active regions, and
wherein a top surface of the first portion of the second gate line is lower than a top surface of the second portion of the first gate line.

17. The device of claim 16, wherein a distance between the top surface of the first portion of the second gate line and a top surface of the device isolation layer at which the first gate line is positioned is greater than a distance between the top surface of the second portion of the first gate line and the top surface of the active region at which the first gate line is positioned, and wherein the top surface of the device isolation layer and the top surface of the active region at which the first gate line is positioned extend along a same axis.

18. The device of claim 16, further comprising a doped region formed in each of the active regions, wherein the doped region comprises a first doped region between the first gate line and a third gate line, and a second doped region between the first and second gate lines.

19. The device of claim 18, wherein the first doped region extends into the substrate having a depth that is greater than a depth of the second doped region.

20. The device of claim 18, wherein a distance from a top surface of the second doped region to a top surface of the first portion of the second gate line is greater than a distance from a top surface of the second doped region to a top surface of the second portion of the first gate line.
